(19) United States
(12) Patent Application Publication
(10) Pub. No.: US 2014/0009140 A1
(43) Pub. Date: Jan. 9, 2014

(54) SYSTEM FOR TESTING REAL TIME CLOCK

(71) Applicant: QIANG GUO, Shenzhen City (CN)

(72) Inventor: QIANG GUO, Shenzhen City (CN)

(21) Appl. No.: 13/664,435

(22) Filed: Oct. 31, 2012

(30) Foreign Application Priority Data
Jul. 3, 2012 (CN) 2012102268307

(51) Int. Cl. G01R 23/15

(52) U.S. Cl. 324/76.41

(57) ABSTRACT

A system for testing a real time clock (RTC) includes a frequency-dividing circuit configured to generate a frequency-dividing clock pulse signal equal to a rated frequency of a clock pulse signal generated by the RTC, and a control circuit including a processing chip. The processing chip includes a timer and a counter. The timer is used to record a test time of the RTC, the counter is used to record a pulse difference between the clock pulse signal and the frequency-dividing clock pulse signal during the test time. If a pulse rate difference between the counter and the timer is greater than a standard clock pulse difference, the RTC is unqualified, and if the pulse rate difference between the counter and the timer is less than the standard clock pulse difference, the RTC is qualified.

### BACKGROUND

1. Technical Field

The present disclosure relates to a system for testing a real time clock (RTC).

2. Description of Related Art

A system time of a computer is provided by an RTC. The RTC uses a crystal oscillator to output a pulse signal to provide the system time. A frequency of the pulse signal may be 32.768 kilohertzs (KHz). However, the crystal oscillator is temperature sensitive, and at a particular temperature the frequency of the pulse signal outputted by the crystal oscillator may not equal to 32.768 KHz. Consequently, an average frequency is used to determine whether a crystal oscillator is qualified to be a component of the RTC or not. However, many of the present method of averaging the frequency of the crystal oscillator are based on analog data observed by humans. Thus, the test result may be inaccurate.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a block diagram of an embodiment of a system for testing a real time clock (RTC) of the present disclosure.

FIG. 2 is a partial circuit diagram of the system of FIG. 1, wherein the system includes an amplifying circuit, a frequency-dividing circuit, a control circuit, a display circuit, and a power circuit.

FIG. 3 is block diagram of a processing chip of FIG. 2.

### DETAILED DESCRIPTION

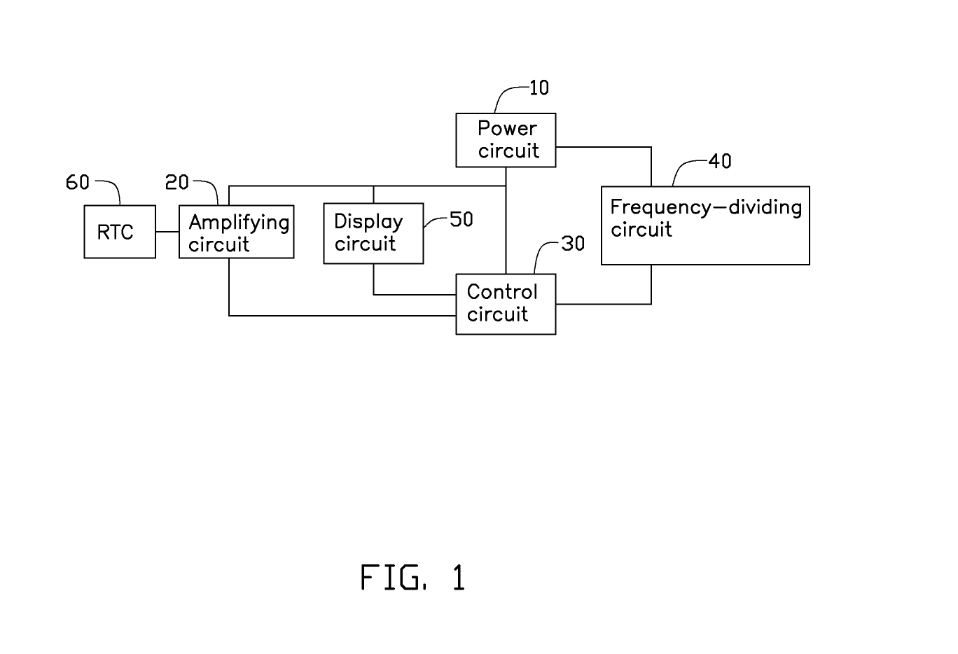

FIG. 1 illustrates an embodiment of a system for testing a real time clock (RCT) 60 of the present disclosure. The system includes an amplifying circuit 20, a frequency-dividing circuit 40, a control circuit 30, a display circuit 50, and a power circuit 10 configured to supply power to the amplifying circuit 20, the frequency-dividing circuit 40, and the control circuit 30.

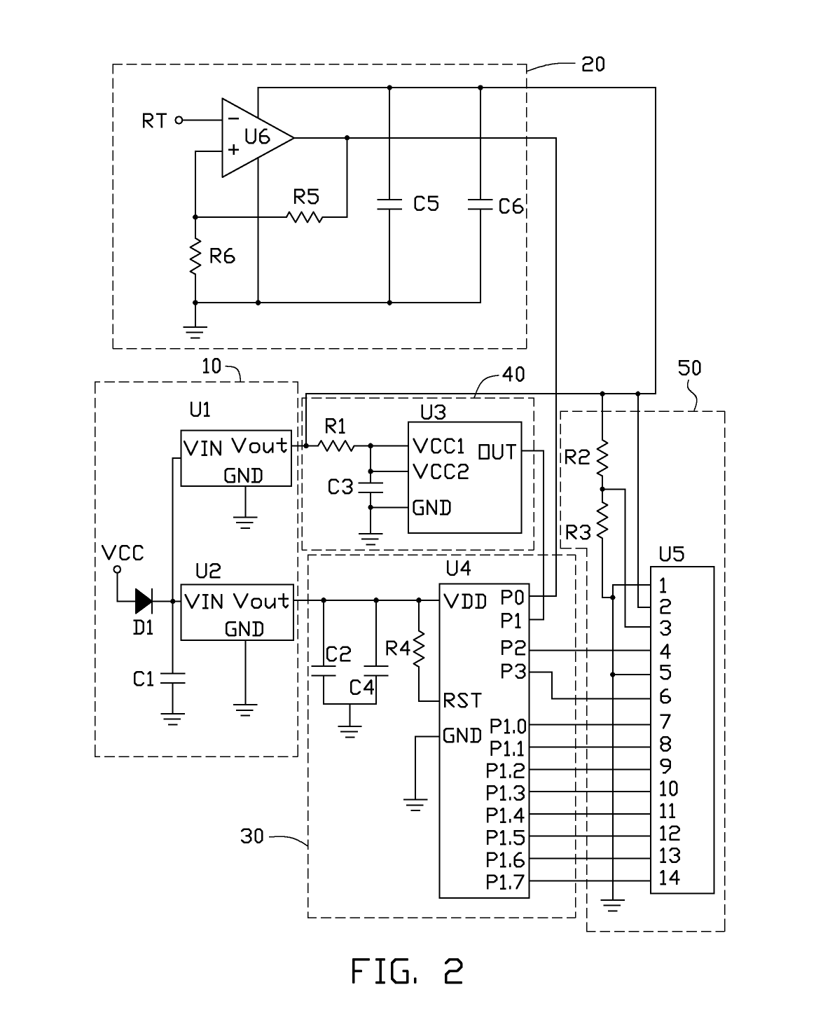

FIG. 2 illustrates a detailed partial circuit diagram of the system. The power circuit 10 includes a diode D1, a capacitor C1, and two power chips U1 and U2. Ground pins GND of the power chips U1 and U2 are grounded. Input pins VIN of the power chips U1 and U2 are coupled to a cathode of the diode D1, and are grounded through the capacitor C1. An anode of the diode D1 is coupled to a power terminal VCC. The power chip U1 is utilized to convert the voltage of the power terminal VCC into a first power source, and outputs the first power source through an output pin Vout of the power chip U1 to the frequency-dividing circuit 40 and the amplifying circuit 20. The power chip U2 is utilized to convert the voltage of the power terminal VCC into a second power source, and outputs the second power source through an output pin Vout of the power chip U2 to the control circuit 30.

The amplifying circuit 20 is used to receive a clock pulse signal RT output by the RTC 60, amplify the clock pulse signal RT, and output an amplified clock pulse signal. The amplifying circuit 20 includes an amplifier U6, two resistors R5 and R6, and two capacitors C5 and C6. A power pin of the amplifier U6 is coupled to the output pin Vout of the power chip U1, and is grounded through the capacitors C5 and C6 connected in parallel. A ground pin of the amplifier U6 is grounded. An inverting input pin of the amplifier U6 is connected to the RCT 60 to receive the clock pulse signal RT. A non-inverting input pin of the amplifier U6 is grounded through the resistor R6, and coupled to an output pin of the amplifier U6 through the resistor R5. The output pin of the amplifier U6 is utilized to output the amplified clock pulse signal. In the embodiment, a rated frequency of the amplified clock pulse signal is 32.768 kilohertzs (KHz). In an actual working state, the actual frequency of the amplified clock pulse signal may not be equal to 32.768 KHz because of the temperature of a crystal oscillator of the RTC 60.

The frequency-dividing circuit 40 is utilized to output a frequency-dividing clock pulse signal. The frequency-dividing circuit 40 includes a resistor R1, a capacitor C3, and a frequency-dividing chip U3. Power pins VCC1 and VCC2 of the frequency-dividing chip U3 are coupled to the output pin Vout of the power chip U2 through the resistor R1, and are grounded through the capacitor C3. A ground pin of the frequency-dividing chip U3 is grounded. An output pin OUT of the frequency-dividing chip U3 is used to output the frequency-dividing pulse signal. In the embodiment, the frequency-dividing chip U3 generates a standard frequency of 16.384 magehertzs (MHz). Dividing the standard frequency of 16.384 MHz by 500 is made by the frequency-dividing chip U3. The frequency-dividing chip U3 outputs the frequency-dividing clock pulse signal with a divided frequency in accordance with the rated frequency of the amplified pulse signal of the RTC 60 through the output pin OUT. The divided frequency is 16.384 MHz/500=32.768 KHz.

The control circuit 30 includes a processing chip U4, two capacitors C2 and C4, and a resistor R4. A power pin VDD of the processing chip U4 is coupled to the output pin Vout of the power chip U2, and is grounded through the capacitors C2 and C4 connected in parallel. A ground pin GND of the processing chip U4 is grounded. A reset pin RST of the processing chip U4 is coupled to the power pin VDD through the resistor R4. An amplified clock pulse signal receiving pin P0 of the processing chip U4 is connected to the output pin of the amplifier U6 of the amplifying circuit 20, to receive the amplified clock pulse signal. A frequency-dividing clock pulse signal receiving pin P1 is connected to the output pin OUT of the frequency-dividing chip U3 of the frequency-dividing circuit 40, to receive the frequency-dividing pulse signal.

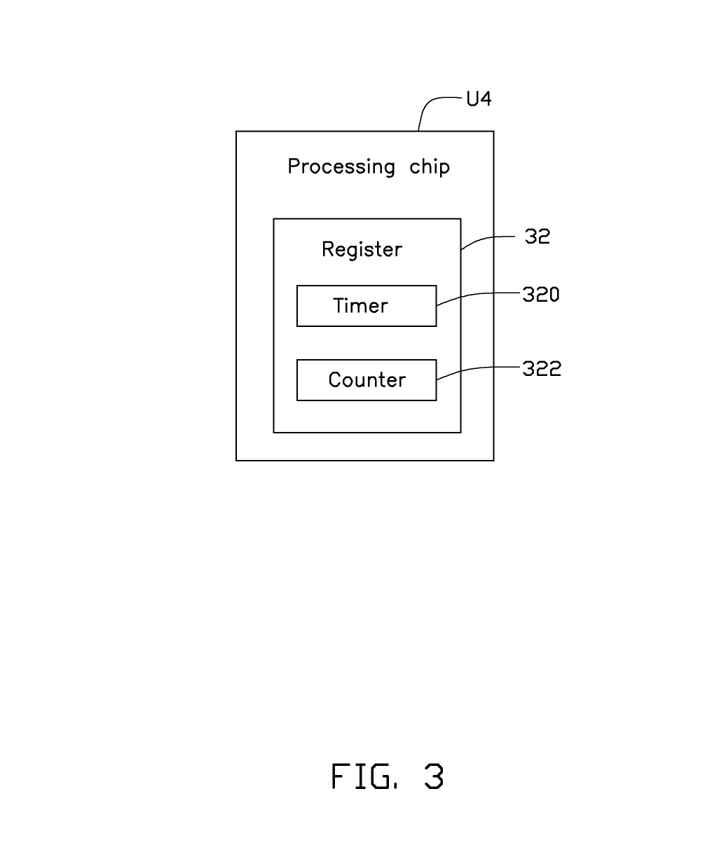

FIG. 3 illustrates a block diagram of the processing chip U4. In the embodiment, the processing chip U4 may be a micro control unit (MCU) that includes a register 32 to execute instructions to perform certain functions. The processing chip U4 includes a counter 322 and a timer 320 integrated in the register 32. When receiving one amplified clock pulse signal from the amplified clock pulse signal receiving pin P0, the counter 322 is increased by 1, and when receiving one frequency-dividing clock pulse signal from the frequency-dividing clock pulse signal receiving pin P1, the counter 322 is decreased by 1. The timer 320 is configured to record the test time.

A frequency of 32.768 KHz stands for 32768 times pulse signal output in 1 second. In the embodiment, if a pulse rate difference X between the standard time of the frequency-dividing circuit 40 and the actual time of the RTC 60 in 24 hours is less than 2 seconds, which means the pulse difference equal to 32768*2 times, the RTC 60 is qualified. In the embodiment, the counter 322 is a binary counter with 32 bits. The expression that the processing chip U4 determines whether the RTC 60 is qualified or not is shown below:

X<=2s*32768(t/s)/(24*60*60s)=0.758(t/s).

It indicates that a standard pulse difference of the frequency in 1 second between the amplified clock pulse signal and the frequency-dividing clock pulse signal should be within 0.758 times on average. If the pulse rate difference between the amplified clock pulse signal and the frequency-dividing clock pulse signal is greater than the standard pulse difference, the RTC 60 is not qualified. Alternatively, if the pulse rate difference between the amplified clock pulse signal and the frequency-dividing clock pulse signal is less than the standard pulse difference, the RTC 60 is qualified.

For example, if the counter 322 is 600 times, and the timer 320 is 750 seconds, the pulse rate difference between the amplifying clock pulse signal and the frequency-dividing clock pulse signal is 600 t/750 s=0.8 t/s. The RTC 60 is not qualified because the pulse rate difference 0.8 t/s is greater than the standard pulse difference 0.758 t/s.

The display circuit 50 includes a display chip U5 and two resistors R2 and R3. A power pin 2 of the display chip U5 is coupled to the output pin Vout of the power chip U1. A power pin 3 of the display chip U5 is coupled to the output pin Vout of the power chip U1 through the resistor R2, and is grounded through the resistor R3. A ground pin 1 of the display chip U5 is grounded. A chip select pin 4 of the display chip U5 is coupled to a pin P2 of the processing chip U4. Eight data pins 7-14 of the display chip U5 are coupled to eight pins P1.0-P1.7 of the processing chip U4, respectively. The display chip U5 is used to display the value of the counter 322 and the timer 320, and the test result. For example, the display chip U5 would display “counter is 600 times, timer is 750 seconds, and the test is failure”.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A system for testing a real time clock (RTC), comprising:
a frequency-dividing circuit configured to generate a frequency-dividing clock pulse signal, wherein a frequency of the frequency-dividing clock pulse signal is equal to a rated frequency of a clock pulse signal generated by the RTC; and
a control circuit comprising a processing chip, wherein the processing chip is operable to receive the clock pulse signal and the frequency-dividing clock pulse signal, the processing chip comprises a counter and a timer, wherein the timer is operable to record a test time of the RTC, the counter is operable to record a clock pulse difference between the clock pulse signal and the frequency-dividing clock pulse signal during the test time;
wherein if a pulse rate difference between the counter and the timer is greater than a standard clock pulse difference, the RTC is unqualified, and if the pulse rate difference between the counter and the timer is less than the standard clock pulse difference, the RTC is qualified.

2. The system of claim 1, wherein the counter is increased by 1 in response to the processing chip receiving one clock pulse signal, the counter is decreased by 1 in response to the processing receiving one frequency-dividing clock pulse signal.

3. The system of claim 1, further comprising an amplifying circuit, wherein the amplifying circuit is operable to amplify the clock pulse signal, and outputs an amplified clock pulse signal.

4. The system of claim 3, further comprising a power circuit supplying power for the frequency-dividing circuit and the control circuit.

5. The system of claim 4, wherein the amplifying circuit comprises an amplifier and a first resistor, wherein an inverting input pin of the amplifier is operable to receive the clock pulse signal, a non-inverting input pin of the amplifier is grounded, a power pin of the amplifier is coupled to the power circuit, a ground pin of the amplifier is grounded, and an output pin of the amplifier is operable to output the amplified clock pulse signal, and coupled to the non-inverting pin of the amplifier through the first resistor.

6. The system of claim 5, wherein the amplifying circuit further comprises first and second capacitors, and a second resistor, the non-inverting input pin is grounded through the second resistor, and the output pin of the amplifier chip is grounded through the first and second capacitors connected in parallel.

7. The system of claim 5, wherein the frequency-dividing circuit comprises a frequency-dividing chip generating a standard clock pulse signal, wherein a power pin of the frequency-dividing chip is coupled to the power circuit, the frequency-dividing chip is operable to divide the standard clock pulse signal by a certain number to generate the frequency-dividing clock pulse signal.

8. The system of claim 7, wherein the power circuit comprises a first power chip and a second power chip, input pins of the first and second power chips are coupled to a power terminal, ground pins of the first and second power chips are grounded, the first power chip is operable to convert a voltage of the power terminal into a first power source, and output the first power source through an output pin of the first power chip to the frequency-dividing circuit and the amplifying circuit, the second power chip is operable to convert the voltage of the power terminal into a second power source, and output the second power source through an output pin of the second power chip to the control unit.

9. The system of claim 8, wherein the power circuit further comprises a diode and a third capacitor, wherein an anode of the diode is coupled to the power terminal, a cathode of the diode is couple to the input pins of the first and second power chips, the input pins of the first and second power chips are grounded through the third capacitor.

10. The system of claim 9, wherein the frequency-dividing circuit further comprises a third resistor and a fourth capacitor, a first and a second power pins of the frequency-dividing chip are coupled to the output pin of the first power chip through the third resistor, and are grounded through the fourth capacitor, a ground pin of the frequency-dividing chip is grounded, an output pin of the frequency-dividing chip outputs the frequency-dividing clock pulse signal.

11. The system of claim 1, further comprising a display circuit, wherein the display circuit comprises a display chip connected to the control circuit, the display chip is operable to display values of the counter and the timer, and a result of the test.
